(19) United States
(12) Patent Application Publication
(10) Pub. No.: US 2022/0320034 A1
(43) Pub. Date: Oct. 6, 2022

(54) MOUNTING APPARATUS

(71) Applicant: SHINKAWA LTD., Tokyo (JP)

(72) Inventors: Hijiri HAYASHI, Tokyo (JP); Tetsuya UTANO, Tokyo (JP); Kohei SEYAMA, Tokyo (JP)

(73) Assignee: SHINKAWA LTD., Tokyo (JP)

(21) Appl. No.: 17/604,747

(22) PCT Filed: Jul. 15, 2020
(86) PCT No.: PCT/JP2020/027468

§ 371 Date: Oct. 18, 2021

(30) Foreign Application Priority Data
Jul. 26, 2019 (JP) 2019-137696

(51) Int. Cl. H01L 23/00

(52) U.S. Cl. CPC H01L 24/75; H01L 25/0652

(57) ABSTRACT

This mounting apparatus is provided with: a plurality of bonding stations each comprising a bonding apparatus for bonding a semiconductor chip onto a substrate wafer, and a chip supply apparatus for supplying the semiconductor chip to the bonding apparatus; and a single wafer transfer apparatus which transfers the substrate wafer in order to supply the substrate wafer to each of the plurality of bonding stations and to collect the substrate wafer from each of the plurality of bonding stations.

### TECHNICAL FIELD

The present specification discloses a mounting apparatus for bonding and mounting a semiconductor chip to a substrate wafer.

### DESCRIPTION OF RELATED ART

Conventionally, a mounting apparatus for manufacturing a semiconductor device by bonding a semiconductor chip onto a substrate has been known. In recent years, a chip-on-wafer type semiconductor device using a wafer as a substrate has been proposed. The mounting apparatus for manufacturing a chip-on-wafer type semiconductor device are provided with a bonding apparatus for bonding a semiconductor chip to a wafer and a wafer transfer apparatus for supplying the wafer functioning as a substrate (hereinafter referred to as a “substrate wafer”) to the bonding apparatus and collecting it from the bonding apparatus. The wafer transfer apparatus is provided with a transfer robot for transferring the wafer without contacting the surface of the substrate wafer, a pre-aligner for correcting the rotation angle of the substrate wafer, and the like. Then, the wafer transfer apparatus takes out the substrate wafer from the load port, corrects the rotation angle of the substrate wafer, and then supplies the substrate wafer to the bonding apparatus. When the bonding process is completed in the bonding apparatus, the wafer transfer apparatus collects the processed substrate wafer from the bonding apparatus, inspects it as necessary, and then transfers the substrate wafer to the load port.

### SUMMARY

### Technical Problem

Here, in order to improve the production capacity for semiconductor devices, it is proposed to provide a plurality of the above-mentioned mounting apparatuses. The production capacity can be improved by operating a plurality of mounting apparatuses in parallel. When a plurality of mounting apparatuses are provided, as a matter of course, not only a bonding apparatus and a chip supply apparatus but also a plurality of wafer transfer apparatuses are provided. However, usually, the time required for transferring and inspecting the substrate wafer is significantly shorter than the time required for the bonding process. Therefore, the wafer transfer apparatus has a long standby time when it is not operated as compared with the bonding apparatus and is wasteful. Providing a plurality of such wafer transfer apparatuses is a waste of space and cost.

Therefore, the present specification discloses a mounting apparatus capable of suppressing an increase in space and cost while improving the production capacity for chip-on-wafer type semiconductor devices.

### Solution to the Problem

A mounting apparatus disclosed in the present specification includes: a plurality of bonding stations, each of which has a bonding apparatus for bonding a semiconductor chip to a substrate wafer and a chip supply apparatus for supplying the semiconductor chip to the bonding apparatus; and one wafer transfer apparatus for transferring the substrate wafer to supply the substrate wafer to each of the plurality of bonding stations and to collect the substrate wafer from each of the plurality of bonding stations.

With such a configuration, since one wafer transfer apparatus can be shared by the plurality of bonding stations, it is possible to suppress an increase in space and cost while improving the production capacity.

Further, the bonding apparatus of each of the plurality of bonding stations may be disposed adjacent to the wafer transfer apparatus, and the chip supply apparatus of each of the plurality of bonding stations may be disposed on an opposite side of the wafer transfer apparatus with the bonding apparatus interposed therebetween.

With such a configuration, the substrate wafer can be supplied and collected without crossing the chip supply apparatus.

Further, the wafer transfer apparatus and the plurality of bonding stations may cooperate with each other to form a chamber, and the wafer transfer apparatus may be capable of transferring the substrate wafer from one bonding station to another bonding station without exposing the substrate wafer to an outside of the chamber.

With such a configuration, it is possible to easily transfer the substrate wafer between the plurality of bonding stations without housing the substrate wafer in a transfer container while preventing contamination of the substrate wafer.

Further, the plurality of bonding stations may include a first bonding station and a second bonding station disposed on an opposite side of the first bonding station with the wafer transfer apparatus interposed therebetween; and the first bonding station, the wafer transfer apparatus, and the second bonding station may be disposed side by side in a row.

With such a configuration, since a dead space can be reduced, the space can be used more effectively.

Further, the mounting apparatus may further include one inspection apparatus for inspecting the substrate wafer that has been processed, and the one inspection apparatus may be shared by the plurality of bonding stations.

With such a configuration, it is possible to prevent an increase in cost and space required for disposing the inspection apparatus.

Further, the wafer transfer apparatus may include one transfer robot for transferring the substrate wafer and one pre-aligner for correcting a rotation angle of the substrate wafer, and the one transfer robot and the one pre-aligner may be shared by the plurality of bonding stations.

Further, the wafer transfer apparatus may have a transfer robot capable of holding two substrate wafers simultaneously, and the transfer robot may be capable of collecting a substrate wafer that has been processed at one bonding station and then supplying a new substrate wafer on the spot without moving.

With such a configuration, the time required for supplying and collecting the substrate wafer can be further shortened.

Further, the plurality of bonding stations may include a first bonding station and a second bonding station, and the wafer transfer apparatus may supply the substrate wafer that has been processed and collected from the first bonding station to the second bonding station.

With such a configuration, two different types of bonding processes can be serially performed on one substrate wafer.

In this case, a temporary crimping process for temporarily crimping the semiconductor chip on the substrate wafer may be executed at the first bonding station, and a permanent crimping process for permanently crimping the temporarily crimped semiconductor chip may be executed at the second bonding station. Further, a process for bonding a first semiconductor chip to the substrate wafer may be executed at the first bonding station, and a process for bonding a second semiconductor chip different from the first semiconductor chip onto the first semiconductor chip may be executed at the second bonding station.

### Effects

According to the mounting apparatus disclosed in the present specification, since one wafer transfer apparatus can be shared by the plurality of bonding stations, it is possible to suppress an increase in space and cost while improving the production capacity.

### BRIEF DESCRIPTION OF THE DRAWINGS

FIG. 1 is a schematic plan diagram of the mounting apparatus.

FIG. 2 is a schematic cross-sectional diagram showing the configuration of a wafer transfer apparatus.

FIG. 3 is a schematic perspective diagram of a transfer robot.

FIG. 4 is a diagram showing another layout example of the mounting apparatus.

FIG. 5 is a diagram showing an example of the operation timing of the mounting apparatus.

FIG. 6 is a diagram showing an example of the operation timing of the mounting apparatus.

FIG. 7 is a diagram showing an example of the operation timing of the mounting apparatus.

FIG. 8 is a diagram showing an example of the operation timing of the mounting apparatus.

FIG. 9 is a diagram showing another layout example of the mounting apparatus.

FIG. 10 is a diagram showing an example of the operation timing of the mounting apparatus.

FIG. 11 is a diagram showing an example of the operation timing of the mounting apparatus.

FIG. 12 is a diagram showing an example of the operation timing of the mounting apparatus.

FIG. 13 is a diagram showing a state of bonding at the first bonding station.

FIG. 14 is a diagram showing a state of bonding at the second bonding station.

FIG. 15 is a diagram showing a state of bonding at the first bonding station.

FIG. 16 is a diagram showing a state of bonding at the second bonding station.

FIG. 17 is a diagram showing an example of the operation timing of the mounting apparatus.

FIG. 18 is a diagram showing an example of the operation timing of the mounting apparatus.

FIG. 19 is a diagram showing an example of the operation timing of the mounting apparatus.

FIG. 20 is a schematic perspective diagram of a transfer robot of another example.

FIG. 21 is a diagram showing an example of the operation timing of the mounting apparatus.

### DESCRIPTION OF THE EMBODIMENTS

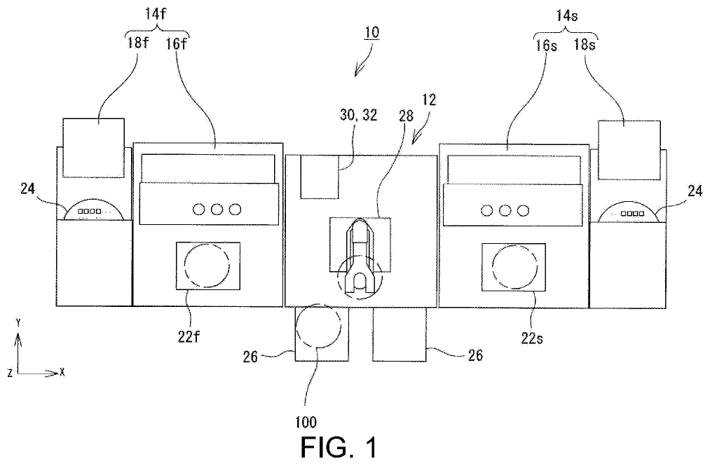

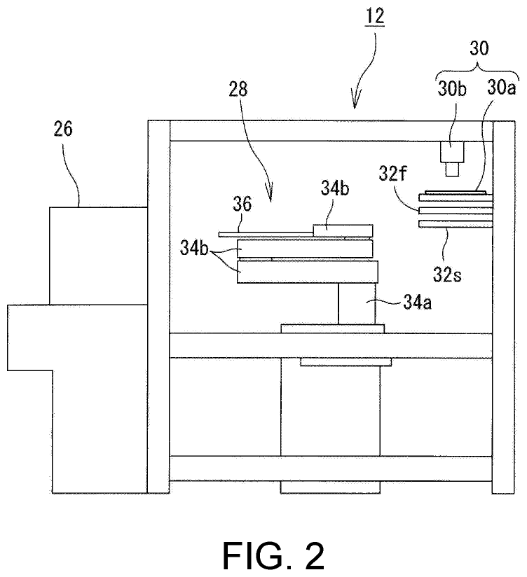

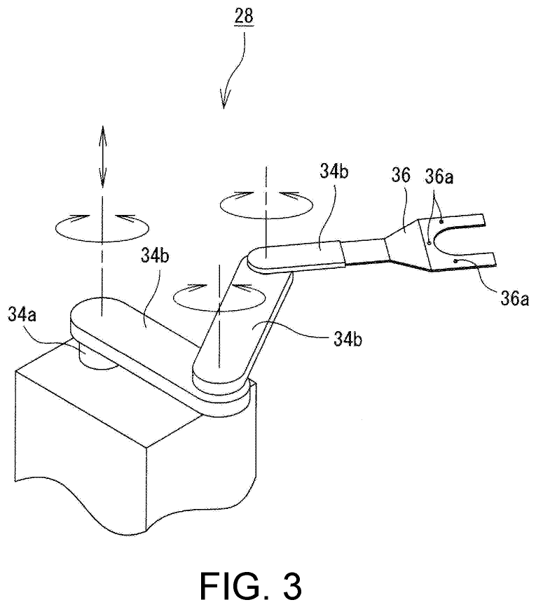

Hereinafter, the configuration of a mounting apparatus 10 will be described with reference to the drawings. FIG. 1 is a schematic plan diagram of the mounting apparatus 10. Further, FIG. 2 is a schematic cross-sectional diagram showing the configuration of a wafer transfer apparatus 12, and FIG. 3 is a schematic perspective diagram of a transfer robot 28.

The mounting apparatus 10 manufactures a semiconductor device in which a semiconductor chip 102 is mounted on a substrate wafer 100, that is, a so-called chip-on-wafer (“COW”) type semiconductor device.

The mounting apparatus 10 includes the wafer transfer apparatus 12, a first bonding station 14f, and a second bonding station 14s. In addition, in the following description, when the first and second bonding stations are not distinguished, the subscripts f and s are omitted, and they are simply referred to as the “bonding stations 14”. The same applies for other elements. The first and second bonding stations 14f and 14s have the same configuration as each other. Further, the wafer transfer apparatus 12 and the two bonding stations 14f and 14s cooperate with each other to form a chamber. Therefore, the wafer transfer apparatus 12 is capable of transferring the substrate wafer 100 from one bonding station 14 to another bonding station 14 without exposing the substrate wafer 100 to the outside of this chamber.

Each bonding station 14 includes a bonding apparatus 16 and a chip supply apparatus 18 disposed adjacent to the bonding apparatus 16 in the X direction. The bonding apparatus 16 bonds the semiconductor chip 102 to the substrate wafer 100, and has a bonding stage 22 on which the substrate wafer 100 is placed. A bonding head (not shown in FIG. 1) that attracts and transfers the semiconductor chip 102 is provided above the bonding stage 22. The bonding head 38 electrically and mechanically fixes the semiconductor chip 102, which is attracted and held, onto the substrate wafer 100 by pressing and heating the surface of the substrate wafer 100.

The chip supply apparatus 18 is an apparatus that supplies the semiconductor chip 102 to the bonding apparatus 16, and has a chip supply source 24. A chip picker (not shown) picks up the semiconductor chip 102 in the chip supply source 24, transfers it, and supplies it to the bonding head 38. Known conventional technology can be used as the configuration of the chip supply apparatus 18, and therefore detailed description thereof will be omitted here.

The wafer transfer apparatus 12 is an apparatus that supplies the substrate wafers 100 to both of the two bonding stations 14 and collects the processed substrate wafers 100 from the two bonding stations 14. In this example, the wafer transfer apparatus 12 is provided between the two bonding stations 14. More specifically, the first chip supply apparatus 18f, the first bonding apparatus 16f, the wafer transfer apparatus 12, the second bonding apparatus 16s, and the second chip supply apparatus 18s are disposed side by side in a row in the X direction in this order. From another point of view, the two bonding stations 14 are symmetrically disposed or mirror-disposed with the wafer transfer apparatus 12 as the center. Further, the bonding apparatus 16 of each of the two bonding stations 14 is disposed adjacent to the wafer transfer apparatus 12, and the chip supply apparatus 18 of each of the plurality of bonding stations 14 is disposed on an opposite side of the wafer transfer apparatus 12 with the bonding apparatus 16 interposed therebetween.

The wafer transfer apparatus 12 transfers the substrate wafer 100, but the upper surface of the substrate wafer 100 is required to be kept normal and cannot be contacted. Therefore, the wafer transfer apparatus 12 is provided with the transfer robot 28 for transferring the substrate wafer 100 while attracting and holding the bottom surface of the substrate wafer 100. As shown in FIG. 3, the transfer robot 28 is an articulated robot having a plurality of arms 34. The configuration of this articulated robot is not particularly limited, but in this example, the transfer robot 28 includes a root arm 34a capable of extending and contracting in the Z-axis direction, a plurality of intermediate arms 34b capable of rotating on a horizontal plane, and a holding hand 36 provided at the tip of the articulated robot. A plurality of attraction holes 36a for attracting and holding the substrate wafer 100 are formed on the surface of the holding hand 36. The transfer robot 28 has a movable range that allows access to both the first bonding stage 22f and the second bonding stage 22s.

Load ports 26 for loading and unloading the substrate wafers 100 is provided at the front end of the wafer transfer apparatus 12. In this example, two load ports 26 are provided, but the number of load ports 26 may be one or three or more. Further, the plurality of load ports 26 may be divided into a loading port at which the unprocessed substrate wafer 100 stands by and an unloading port at which the processed substrate wafer 100 that has been subjected to the mounting process stands by. Further, the plurality of load ports 26 may be divided into a port for housing the substrate wafer 100 handled by the first bonding station 14f and a port for housing the substrate wafer 100 handled by the second bonding station 14s.

Further, the wafer transfer apparatus 12 is also provided with a pre-aligner 30 for correcting the rotation angle of the substrate wafer 100. Specifically, the substrate wafer 100 is usually provided with a straight line part called an orientation flat or a notch serving as a marker for defining the rotation angle of the substrate wafer 100. When the substrate wafer 100 is supplied to the bonding stage 22 and placed on the bonding stage 22, the marker on the substrate wafer 100 must be placed in a predetermined orientation (rotation angle). Therefore, the pre-aligner 30 is provided to check and correct the rotation angle of the substrate wafer 100 before supplying the substrate wafer 100 to the bonding stage 22. The pre-aligner 30 has, for example, a rotary table 30a on which the substrate wafer 100 is placed, and a camera 30b which images the substrate wafer 100.

First and second standby stages 32f and 32s are provided on the lower side of the pre-aligner 30. The standby stages 32 are stages on which the substrate wafers 100 subjected to the bonding process is placed. The standby stages 32 are used, for example, to cool the substrate wafers 100 in a high temperature state after the bonding process.

In the mounting apparatus 10 having the above configuration, one transfer robot 28 and one pre-aligner 30 are used to supply and collect the substrate wafers 100 handled by the plurality of bonding stations 14 and to correct the rotation angle. In other words, in this example, one wafer transfer apparatus 12 is shared by the plurality of bonding stations 14. With such a configuration, COW type semiconductor devices can be manufactured more efficiently.

Specifically, most of the conventional mounting apparatuses 10 are provided with one wafer transfer apparatus 12 for one bonding station 14. Therefore, in order to improve the manufacturing capacity, when two bonding stations 14 are provided, two wafer transfer apparatuses 12 are also provided. However, usually, a large number of semiconductor chips 102 are bonded to one substrate wafer 100, and the time of the bonding process executed by the bonding apparatus 16 is significantly longer than the time required for transferring the substrate wafer 100 and correcting the rotation angle. Therefore, the wafer transfer apparatus 12 has a long standby time when it is not driven as compared with the bonding apparatus 16 and is wasteful. Furthermore, the wafer transfer apparatus 12 has the transfer robot 28 and the like as described above. Therefore, when a plurality of wafer transfer apparatuses 12 are provided, the burden on space and cost is large.

Therefore, in this example, it is configured that a plurality of bonding stations 14 are provided, and the plurality of bonding stations 14 share one wafer transfer apparatus 12. By providing the plurality of bonding stations 14, the production capacity for semiconductor devices can be improved. In addition, since one wafer transfer apparatus 12 alone is sufficient, it is possible to suppress an increase in cost and space required for the wafer transfer apparatus 12.

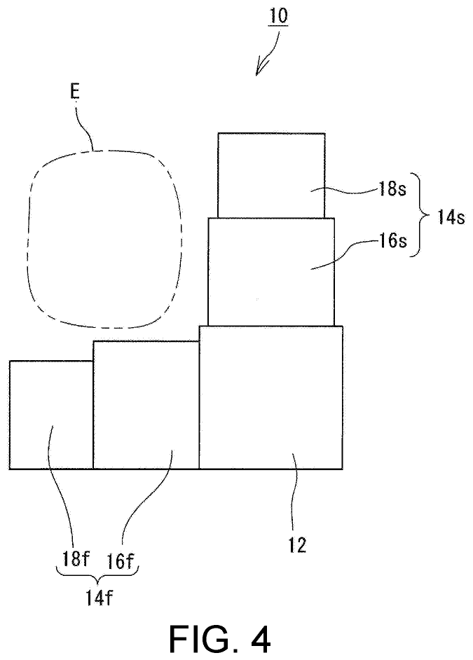

Further, as described above, in this example, two bonding stations 14 are mirror-disposed with the wafer transfer apparatus 12 as the center. With such a disposition, a dead space can be reduced. Specifically, the disposition mode of the two bonding stations 14 is not limited to the mirror disposition as shown in FIG. 1, and other dispositions are also conceivable. For example, as shown in FIG. 4, it is conceivable to adopt an L-shaped disposition in which the first bonding station 14f is disposed in the X direction and the second bonding station 14s is disposed in the Y direction when viewed from the wafer transfer apparatus 12. However, in the case of such a disposition, the area E surrounded by the L shape is likely to become a dead space, and the layout in the factory is likely to be difficult. On the other hand, if the mirror disposition (or one row disposition) as shown in FIG. 1 is adopted, a dead space is less likely to occur, and the layout in the factory becomes easy. However, as a matter of course, if there is no problem in terms of space, the L-shaped disposition as shown in FIG. 4 may be adopted. Further, in any disposition, it is preferable that the bonding apparatus 16 of each of the plurality of bonding stations 14 is disposed adjacent to the wafer transfer apparatus 12. With such a disposition, the transfer robot 28 can reach the bonding apparatus 16 without crossing the chip supply apparatus 18. As a result, it is not necessary to increase the movable range of the transfer robot 28; therefore, it is possible to prevent the transfer robot 28 from becoming large. Further, since the transfer robot 28 does not cross the chip supply apparatus 18, interference between the transfer robot 28 and other members can also be effectively suppressed.

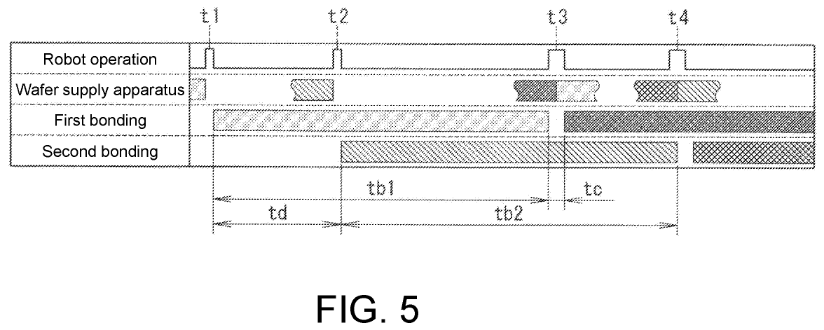

Next, the flow of the mounting process in the mounting apparatus 10 will be described. FIGS. 5 to 8 are timing charts showing the operation timing of the transfer robot 28 and the staying locations of the substrate wafers 100. In FIGS. 5 to 8, the first stage shows the timing at which the transfer robot 28 is transferring the substrate wafers 100. Further, the second and subsequent stages indicate the staying locations of the substrate wafers 100. More specifically, among the substrate wafers 100 handled by the first bonding station 14f, an odd-numbered substrate wafer 100 (hereinafter referred to as the “first odd-numbered wafer W1O”) is shown as a light ink strip, and an even-numbered substrate wafer 100 (hereinafter referred to as the “first even-numbered wafer W1E”) is shown as a dark ink strip. Further, among the substrate wafers 100 handled by the second bonding station 14s, an odd-numbered substrate wafer 100 (hereinafter referred to as the “second odd-numbered wafer W2O”) is shown as a diagonally hatched strip, and an even-numbered substrate wafer 100 (hereinafter referred to as the “second even-numbered wafer W2E”) is shown as a cross-hatched strip.

FIG. 5 is the most basic timing chart. As shown in FIG. 5, the transfer robot 28 first transfers the first odd-numbered wafer W1O (light ink) from the wafer transfer apparatus 12 to the first bonding station 14f (t1). The bonding process is executed on the first odd-numbered wafer W1O at the first bonding station 14f. As shown in FIG. 5, the time required for this bonding process is significantly longer than the time required for transfer. Therefore, the transfer robot 28 transfers the second odd-numbered wafer W2O (diagonally hatched) from the wafer transfer apparatus 12 to the second bonding station 14s (t2) while the bonding process is being executed on the first odd-numbered wafer W1O.

When the bonding apparatus 16 at the first bonding station 14f completes the process (t3), the transfer robot 28 collects the first odd-numbered wafer W1O to the wafer transfer apparatus 12, and then transfers the first even-numbered wafer W1E (dark ink) to the first bonding station 14f. The bonding process is executed on the first even-numbered wafer W1E at the first bonding station 14f. The bonding process of the second odd-numbered wafer W2O is completed (t4) while the bonding process is being executed on the first even-numbered wafer W1E. In this state, the transfer robot 28 collects the second odd-numbered wafer W2O to the wafer transfer apparatus 12, and then transfers the second even-numbered wafer W2E (cross-hatched) to the second bonding station 14s. After that, the same process is repeated.

As described above, while the bonding process is being executed at one bonding station 14, the substrate wafer 100 is supplied or collected to the other bonding station 14. With such a configuration, since the timings of supply and collection of the substrate wafers 100 are staggered at the first and second bonding stations 14s, one wafer transfer apparatus 12 can be shared by the plurality of bonding stations 14. In addition, as a matter of course, the transfer timings of the substrate wafers 100 at the two bonding stations 14f and 14s are staggered so that the replacement timings of the substrate wafers 100 do not overlap between the first bonding station 14f and the second bonding station 14s. Specifically, in the case of setting the time of the bonding process at the first and second bonding stations 14f and 14s to tb1 and tb2, the time required for the replacement of the substrate wafer 100 to tc, and the time difference of the transfer timings of the substrate wafers 100 at the two bonding stations 14f and 14s to td, it is necessary to satisfy the condition of tb1+tc<tb2+td. Therefore, when the same type of semiconductor devices are manufactured at the first and second bonding stations 14f and 14s, and tb1=tb2, the time difference td may be made greater than the replacement time tc of the substrate wafer 100 (that is, tc<td).

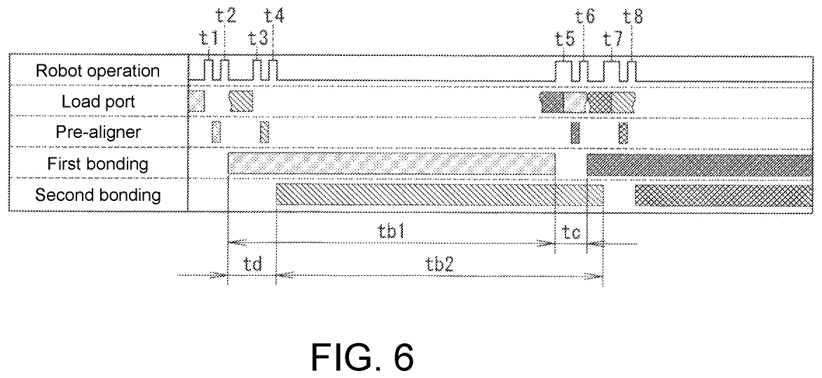

Next, a more specific operation timing will be described with reference to FIG. 6. In the example of FIG. 6, each substrate wafer 100 is housed in the load port 26, and is supplied from the load port 26 to the bonding stations 14 via the pre-aligner 30. Specifically, the transfer robot 28 transfers the first odd-numbered wafer W1O (light ink) from the load port 26 to the pre-aligner 30 (t1). In the pre-aligner 30, the rotation angle of the first odd-numbered wafer W1O is checked and corrected as necessary. When the correction of the rotation angle is completed, the transfer robot 28 supplies the first odd-numbered wafer W1O from the pre-aligner 30 to the first bonding station 14f (t2). The bonding process is executed on the first odd-numbered wafer W1O at the first bonding station 14f.

When the bonding process for the first odd-numbered wafer W1O is started, the transfer robot 28 transfers the second odd-numbered wafer W2O (diagonally hatched) from the load port 26 to the pre-aligner 30 (t3). Then, when the correction of the rotation angle in the pre-aligner 30 is completed, the transfer robot 28 supplies the second odd-numbered wafer W2O from the pre-aligner 30 to the second bonding station 14s (t4).

When the bonding process of the first odd-numbered wafer W1O is completed, the transfer robot 28 collects the first odd-numbered wafer W1O from the first bonding station 14f to the load port 26, and then transfers the first even-numbered wafer W1E (dark ink) from the load port 26 to the pre-aligner 30 (t5). Then, when the process in the pre-aligner 30 is completed, the first even-numbered wafer W1E is supplied from the pre-aligner 30 to the first bonding station 14f (t6).

Similarly, when the bonding process of the second odd-numbered wafer W2O is completed, the transfer robot 28 collects the second odd-numbered wafer W2O from the second bonding station 14s to the load port 26, and then transfers the second even-numbered wafer W2E (cross-hatched) from the load port 26 to the pre-aligner 30 (t7). Then, when the process in the pre-aligner 30 is completed, the second even-numbered wafer W2E is supplied from the pre-aligner 30 to the second bonding station 14s (t8). After that, the same process is repeated.

As described above, in the example of FIG. 6 as well, while the bonding process is being executed at one bonding station 14, the substrate wafer 100 handled by the other bonding station 14 is transferred and the rotation angle is corrected. With such a configuration, one transfer robot 28 and one pre-aligner 30 can be shared by the plurality of bonding stations 14.

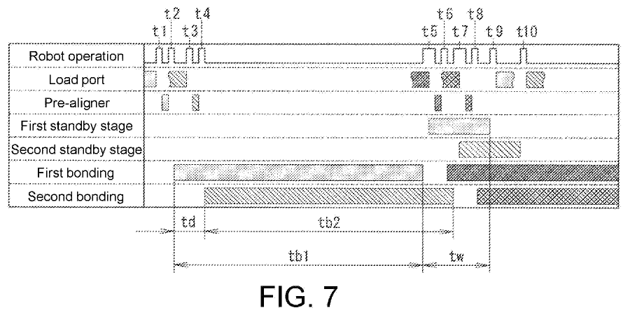

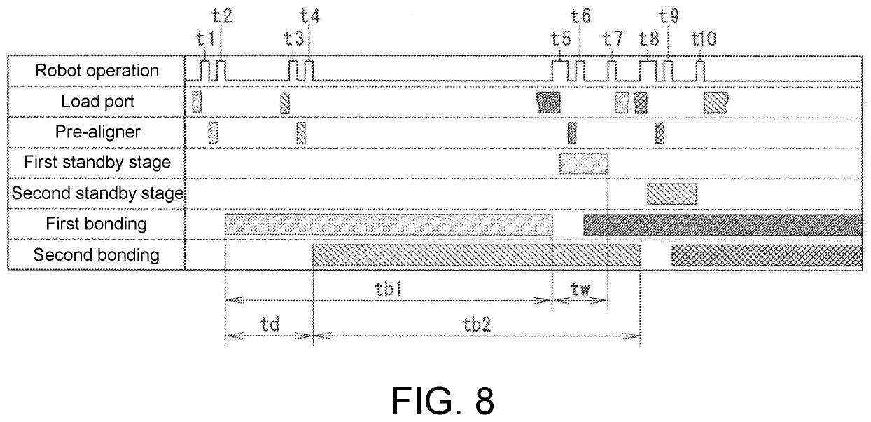

Next, the operation timing when the processed substrate wafer 100 has a high temperature will be described with reference to FIGS. 7 and 8. When the semiconductor chip 102 is bonded to the substrate wafer 100, the semiconductor chip 102 and the substrate wafer 100 may be heated at a high temperature. Therefore, since the substrate wafer 100 immediately after the bonding process is completed has a high temperature, it may not be housed in the load port 26 as it is. In such a case, the processed substrate wafer 100 is temporarily stored on the standby stage 32, cooled, and then transferred to the load port 26. FIGS. 7 and 8 show an example of the operation timing in this case.

First, the example of FIG. 7 will be described. In the example of FIG. 7, the substrate wafer 100 at the second bonding station 14s is replaced while the substrate wafer 100 handled at the first bonding station 14f is standing by at the first standby stage 32f. Specifically, the transfer robot 28 first transfers the first odd-numbered wafer W1O (light ink) to the first bonding station 14f via the pre-aligner 30 (t1, t2). Further, the transfer robot 28 transfers the second odd-numbered wafer W2O (diagonally hatched) to the second bonding station 14s via the pre-aligner 30 (t3, t4) while the first odd-numbered wafer W1O is subjected to bonding.

When the bonding process of the first odd-numbered wafer W1O is completed, the transfer robot 28 transfers the first odd-numbered wafer W1O to the first standby stage 32f instead of the load port 26 (t5). When this transfer is completed, the transfer robot 28 subsequently transfers the first even-numbered wafer W1E (dark ink) to the first bonding station 14f via the pre-aligner 30 (t6). Further, in this example, the bonding process of the second odd-numbered wafer W2O is completed (t7) during the standby period of the first odd-numbered wafer W1O. Therefore, in this example, the substrate wafer 100 at the first bonding station 14f is replaced (t7, t8) during the standby period of the first odd-numbered wafer W1O.

After that, while the bonding process of the first even-numbered wafer W1E and the second even-numbered wafer W2E are being executed, the standby time of the first odd-numbered wafer W1O and the second odd-numbered wafer W2O elapses, and both wafers are sufficiently cooled. In this state, the transfer robot 28 collects the substrate wafer 100 from each standby stage 32 and transfers it to the load port 26 (t9, t10). After that, the same procedure is repeated.

As described above, in the example of FIG. 7 as well, one transfer robot 28 and one pre-aligner 30 can be shared by the plurality of bonding stations 14. In order to replace the substrate wafer 100 at the second bonding station 14s while the substrate wafer 100 is standing by on the first standby stage 32f, as a matter of course, in the case of setting the time of the bonding process in each of the first and second bonding stations 14f and 14s to tb1 and tb2, the time difference in the transfer timings of the substrate wafers 100 in the two bonding stations 14f and 14s to td, and the standby time of the substrate wafer 100 on the first standby stage 32f to tw, it is required that tb1+tw>td+tb2, and in the case of tb1=tb2, the standby time must be greater than the time difference (that is, tw>td). In other words, during the standby period of the substrate wafer 100 handled by one bonding station 14, the substrate wafer 100 is replaced at the other bonding station 14, whereby the time difference td of the transfer timings of the substrate wafers 100 at the two bonding stations 14f and 14s can be shortened, and the overall processing time can be shortened.

Next, an example in which the standby of the substrate wafer 100 handled by one bonding stage 22 and the replacement of the substrate wafer 100 on the other bonding stage 22 do not overlap will be described with reference to FIG. 8. In the example of FIG. 8 as well, similarly to FIG. 7, when the bonding process for the first odd-numbered wafer W1O is completed, the transfer robot 28 transfers the first odd-numbered wafer W1O from the first bonding station 14f to the first standby stage 32f, and then transfers the second even-numbered wafer W2E to the first bonding station 14f (t5, t6). In the example of FIG. 8, the standby time of the first odd-numbered wafer W1O ends (t7) before the bonding process of the second odd-numbered wafer W2O is completed. Therefore, the transfer robot 28 transfers the first odd-numbered wafer W1O from the first standby stage 32f to the load port 26 before replacing the substrate wafer 100 (t8, t9) at the second bonding station 14s. After that, when the bonding process of the second even-numbered wafer W2E is completed, the second odd-numbered wafer W2O is transferred to the second standby stage 32s, and then the second even-numbered wafer W2E is transferred to the second bonding station 14s (t8, t9).

As described above, in the example of FIG. 8 as well, one transfer robot 28 and one pre-aligner 30 can be shared by the plurality of bonding stations 14. Further, according to the example of FIG. 8, the standby time at the first standby stage 32f and the standby time at the second standby stage 32s do not overlap. Therefore, according to this configuration, it is not necessary to provide two standby stages 32, and one standby stage 32 can be shared by the two bonding stations 14f and 14s. In this case, it is necessary to satisfy tb1+tw<td+tb2, and if tb1=tb2, it is necessary to satisfy tw<td.

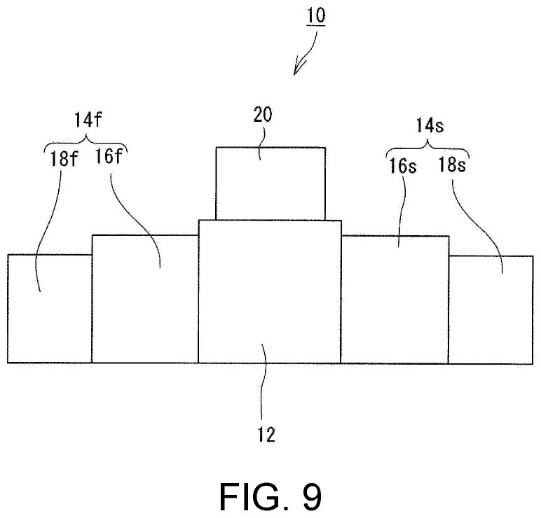

Next, another example will be described. FIG. 9 is an image diagram showing another disposition example of the mounting apparatus 10. In the example of FIG. 9, two bonding stations 14f and 14s are mirror-disposed with one wafer transfer apparatus 12 interposed therebetween, as in the example of FIG. 1. In the example of FIG. 9, an inspection apparatus 20 is further provided on the back side of the wafer transfer apparatus 12 in the Y direction (direction orthogonal to the disposition direction of the two bonding stations 14). The inspection apparatus 20 inspects the processed substrate wafer 100 (that is, the semiconductor device) that has been subjected to the bonding process, and determines the quality of the product. The inspection apparatus 20 includes, for example, a camera, an infrared sensor, and the like. Since a known conventional technique can be used for the configuration of the inspection apparatus 20, detailed description here will be omitted.

Similar to the wafer transfer apparatus 12, only one inspection apparatus 20 is provided, and the inspection apparatus 20 is shared by the plurality of bonding stations 14. With such a configuration, the space and cost required for disposing the inspection apparatus 20 can be reduced. Further, in the example of FIG. 9, the inspection apparatus 20 is disposed outside the wafer transfer apparatus 12, but the inspection apparatus 20 may be incorporated inside the wafer transfer apparatus 12.

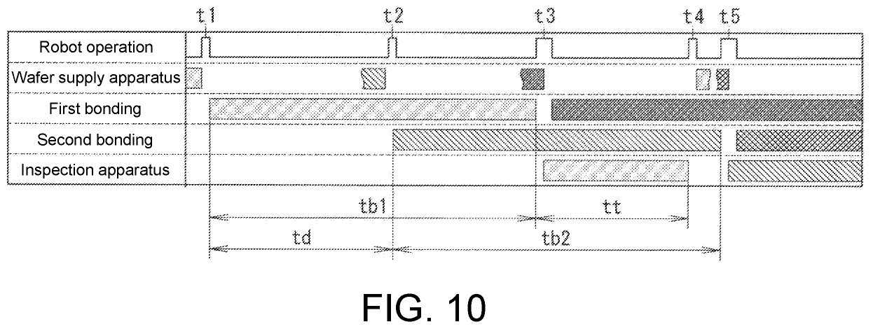

Next, an example of the operation timing when inspecting the processed substrate wafer 100 will be described with reference to FIGS. 10 to 12. FIG. 10 shows the most basic operation timing. In the example of FIG. 10, after the first odd-numbered wafer W1O (light ink) is transferred to the first bonding station 14f (t1) and the time difference td elapses, the second odd-numbered wafer W2O (diagonally hatched) is transferred to the second bonding station 14s (t2). After that, when the bonding process of the first odd-numbered wafer W1O is completed, the transfer robot 28 transfers the first odd-numbered wafer W1O to the inspection apparatus 20, and then transfers the first even-numbered wafer W1E (dark ink) to the first bonding station 14f (t3). Then, when the inspection of the first odd-numbered wafer W1O is completed, the transfer robot 28 transfers the first odd-numbered wafer W1O to the load port 26 of the wafer transfer apparatus 12 (t4). The bonding process of the second odd-numbered wafer W2O is completed (t5) after the inspection of the first odd-numbered wafer W1O is completed. In this state, the transfer robot 28 transfers the second odd-numbered wafer W2O to the inspection apparatus 20, and then transfers the second even-numbered wafer W2E to the second bonding station 14s. After that, the same procedure is repeated.

As is clear from the above description, in this example, in addition to the wafer transfer apparatus 12, the inspection apparatus 20 can also be shared by the plurality of bonding stations 14. As a result, the space and cost required for disposing the inspection apparatus 20 can be reduced. Further, in order to share one inspection apparatus 20 by the two bonding stations 14, it is necessary that the inspection period of the substrate wafer 100 handled by the first bonding station 14f and the inspection period of the substrate wafer 100 handled by the second bonding station 14s do not overlap. For this purpose, in the case of setting the inspection time to tt, it is necessary to satisfy tb1+tt<td+tb2, and when tb1=tb2, it is necessary to set the time difference td greater than the inspection time tt (that is, td>tt).

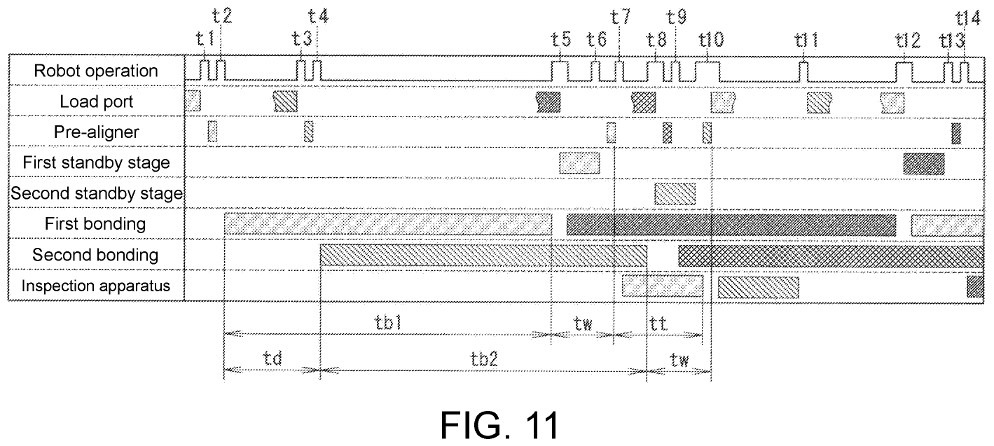

FIG. 11 is a diagram showing a more detailed example of the operation timing. In the example of FIG. 11, the processed substrate wafer 100 obtained by the bonding process stands by once on the standby stage 32, and then is sent to the inspection apparatus 20 via the pre-aligner 30 (t5 to t7, t8 to t10). In this case, in the case of setting the time required for standby and pre-alignment to tw, it is necessary to satisfy tb1+tw+tt<td+tb2+tw, and when tb1=tb2, it is clear that tt<td should be satisfied. Further, in the example of FIG. 11, in order to reduce the time difference td, the substrate wafer 100 at the second bonding station 14s is replaced during the inspection time of the substrate wafer 100 handled by the first bonding station 14f. In such a configuration, tb1+tw+tt>td+tb2 may be set, and when tb1=tb2, the time difference td can be made less than tw+tt. As a result, the overall processing time can be reduced.

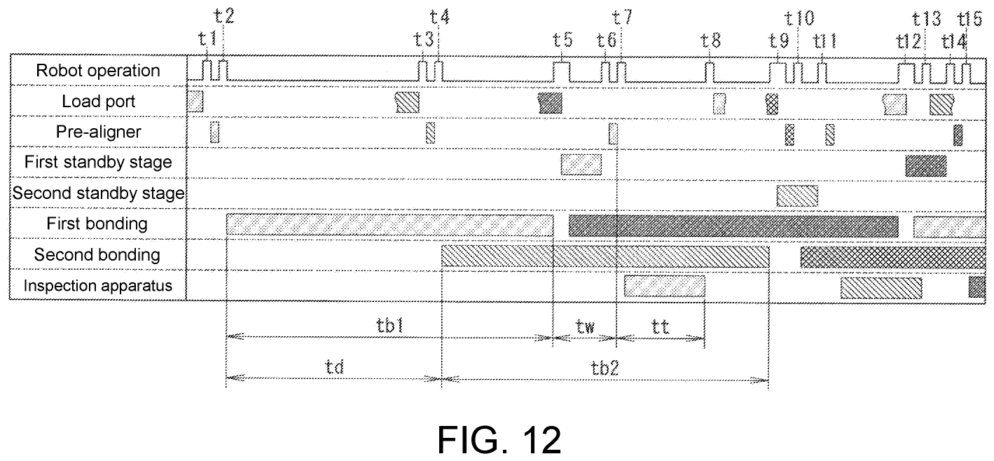

FIG. 12 shows an example in which the processed substrate wafer 100 is inspected, and the inspection of the substrate wafer 100 handled by one bonding stage 22 and the replacement of the substrate wafer 100 on the other bonding stage 22 do not overlap. Specifically, in the example of FIG. 12, the time difference td is set so that the bonding process of the second odd-numbered wafer W2O (diagonally hatched) is completed (t9) after the bonding process, standby, pre-alignment, and inspection of the first odd-numbered wafer W1O (light ink) are completed (t5 to t8). Specifically, it is set that tb1+tw+tt<td+tb2 (when tb1=tb2, tw+tt<td). With such a configuration, overlap of the inspection time can be avoided, so that the number of the standby stage 32 can be reduced to one.

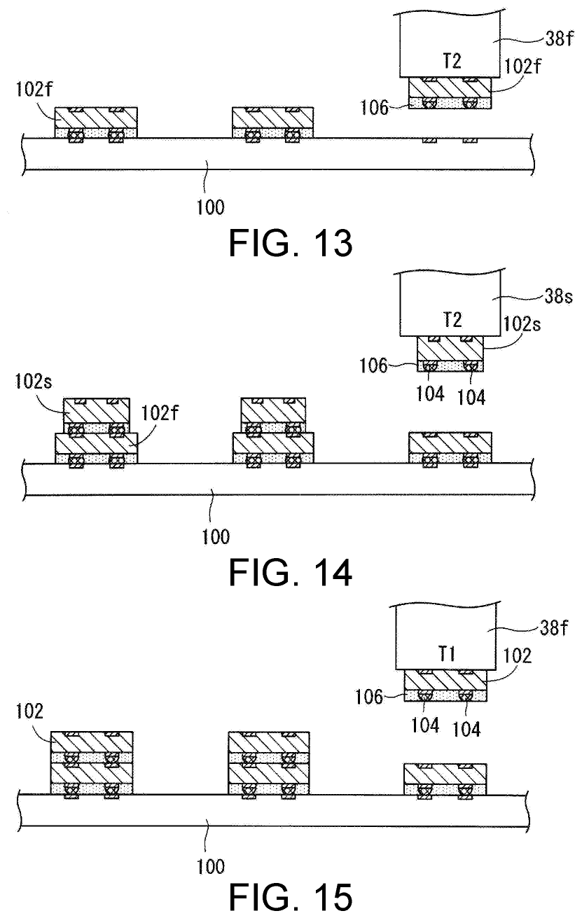

Next, another example will be described with reference to FIGS. 13 to 19. In the above description, the case where the bonding process for one substrate wafer 100 is completed at one bonding station 14 has been described. However, depending on the type of semiconductor devices, it may be more efficient to perform serial processes at the two bonding stations 14. For example, some semiconductor devices are manufactured by stacking two types of semiconductor chips 102 that are different from each other. When such semiconductor chips 102 are manufactured, it is efficient if the first semiconductor chip 102f is bonded by the bonding head 38f of the first bonding station 14f as shown in FIG. 13, and then the second semiconductor chip 102s is bonded onto the first semiconductor chip 102f by the bonding head 38s of the second bonding station 14s as shown in FIG. 14.

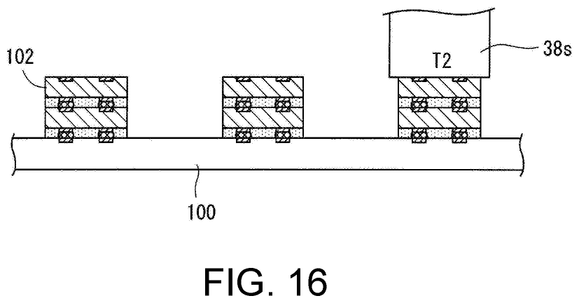

Further, when bonding the semiconductor chip 102, it may be better to perform temporary crimping and permanent crimping separately. Temporary crimping is a step for temporarily placing the semiconductor chip 102, and usually heats and pressurizes the semiconductor chip 102 at a low temperature T1 so that metal bumps 104 are not melted while the thermosetting resin attached to the bottom surface of the semiconductor chip 102 is cured. Further, permanent crimping is a step for finally mounting the temporarily crimped semiconductor chip 102, and usually heats and pressurizes the semiconductor chip 102 at a high temperature T2 so that the metal bumps 104 are melted. Here, when both temporary crimping and permanent crimping are performed at one bonding station 14, it is necessary to switch the temperature of the bonding head 38 and the bonding stage 22, which takes extra time and causes deterioration of production efficiency. Therefore, in such a case, it is efficient if the semiconductor chip 102 is temporarily crimped by the bonding head 38f of the first bonding station 14f as shown in FIG. 15, and then the temporarily crimped semiconductor chip 102 is permanently crimped by the bonding head 38s of the second bonding station 14s as shown in FIG. 16.

Here, in the mounting apparatus 10 of this example, the two bonding stations 14 are connected via the wafer transfer apparatus 12, and the two bonding stations 14 and the wafer transfer apparatus 12 cooperate with each other to form a chamber isolated from the outside. Therefore, in transferring the substrate wafer 100 from the first bonding station 14f to the second bonding station 14s, it is not necessary to take the substrate wafer 100 out of the chamber. Therefore, in transferring the substrate wafer 100, it is not necessary to house the substrate wafer 100 in a transfer container (such as an FOUP) for preventing contamination, and the substrate wafer 100 can be easily transferred.

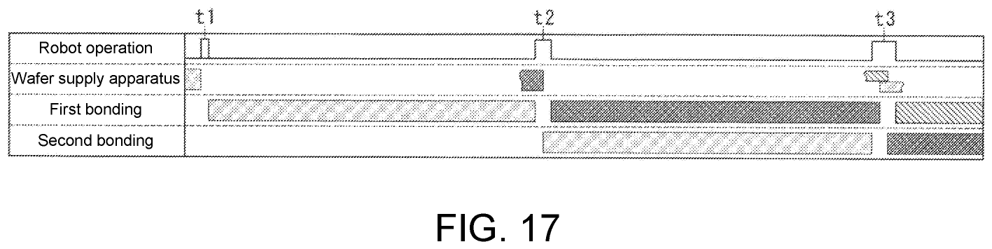

FIGS. 17 to 19 show the operation timings when one substrate wafer 100 is serially processed by the two bonding stations 14. In FIGS. 17 to 19, among the substrate wafers 100 handled by the mounting apparatus 10, the light ink, dark ink, diagonally hatched, and cross-hatched strips show the first, second, third, and fourth substrate wafers 100, respectively.

FIG. 17 shows the most basic operation timing. In the example of FIG. 17, first, the first substrate wafer 100 is transferred from the wafer transfer apparatus 12 to the first bonding station 14f (t1), and the bonding process for the first substrate wafer 100 is executed. When the bonding process for the first substrate wafer 100 is completed, the transfer robot 28 transfers the first substrate wafer 100 from the first bonding station 14f to the second bonding station 14s (t2).

At this point, since the first bonding station 14f has a vacancy, the transfer robot 28 newly transfers the second substrate wafer 100 to the first bonding station 14f. In this way, the bonding process is executed in parallel at the first bonding station 14f and the second bonding station 14s. Then, when the bonding process for the first substrate wafer 100 at the second bonding station 14s is completed, the transfer robot 28 transfers the first substrate wafer 100 to the wafer transfer apparatus 12 (t3). In this way, the processed substrate wafer 100 (semiconductor device) is obtained by subjecting one substrate wafer 100 to the bonding process by the first bonding station 14f and the bonding process by the second bonding station 14s.

When the second bonding station 14s can have a vacancy, the transfer robot 28 transfers the second substrate wafer 100 at the first bonding station 14f to the second bonding station 14s. Then, after that, the same process is repeated.

As is clear from the above description, with the configuration of transferring the substrate wafer 100 from the first bonding station 14f to the second bonding station 14s, two different types of bonding processes can be efficiently performed on one substrate wafer 100.

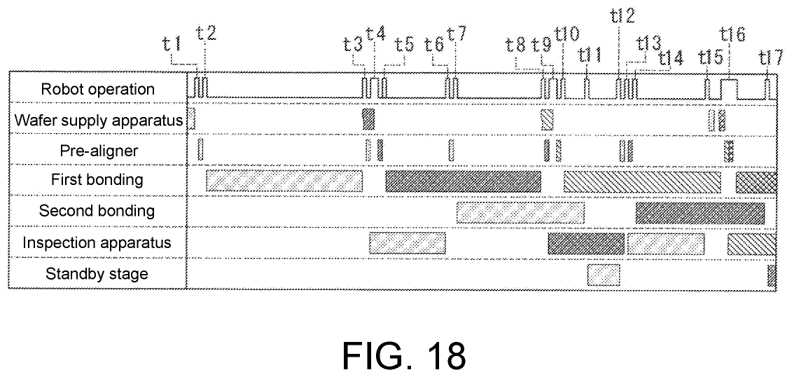

Next, a more specific example of the operation timing will be described with reference to FIG. 18. The example of FIG. 18, as described with reference to FIGS. 15 and 16, is an example of the operation timing when performing a temporary crimping process at the first bonding station 14f and performing a permanent crimping process at the second bonding station 14s on one substrate wafer 100. In the temporary crimping process, since a plurality of semiconductor chips 102 are laminated at one place, the time required for the temporary crimping process is longer than the time required for the permanent crimping process. Further, in the temporary crimping, since the semiconductor chip 102 is heated at a relatively low temperature, cooling (standby) after the process is unnecessary, whereas in the permanent crimping, since the semiconductor chip 102 is heated at a high temperature, cooling (standby) after the process is necessary. Further, every time the temporary crimping and the permanent crimping are completed, the inspection apparatus 20 performs the inspection. When this inspection is performed, the angle of the substrate wafer 100 is corrected by the pre-aligner 30.

More specifically, the first substrate wafer 100 (light ink) is transferred to the first bonding station 14f via the pre-aligner 30 (t1, t2). The temporary crimping process is performed on the substrate wafer 100 at the first bonding station 14f. When this temporary crimping process is completed, the transfer robot 28 transfers the substrate wafer 100 that has been subjected to the temporary crimping process to the inspection apparatus 20 via the pre-aligner 30 (t3, t4). Further, in this state, since the first bonding station 14f has a vacancy, the transfer robot 28 transfers the second substrate wafer 100 (dark ink) to the first bonding station 14f (t4, t5).

When the inspection for the first substrate wafer 100 is completed, the transfer robot 28 transfers the first substrate wafer 100 to the second bonding station 14s via the pre-aligner 30 (t6, t7). The permanent crimping process is performed on the first substrate wafer 100 at the second bonding station 14s. When this permanent crimping process is completed, the inspection apparatus 20 performs the inspection again, but since the substrate wafer 100 after the permanent crimping process has a high temperature, it is first transferred to the standby stage 32 and cooled (t11). When the first substrate wafer 100 can be sufficiently cooled, it is transferred to the inspection apparatus 20 via the pre-aligner 30 (t13, t14). Then, when this inspection is completed, the first substrate wafer 100 is output to the load port 26 (t15). The second substrate wafer 100 is also processed in the same procedure as the first substrate wafer 100. Further, the third and subsequent substrate wafers 100 are also sequentially processed in the same manner.

Here, although there is a slight time difference, the first inspection (from t4) of the first substrate wafer 100 (light ink) and the temporary crimping process (from t5) of the second substrate wafer 100 (dark ink) are started substantially simultaneously. Then, in order to avoid overlap of the first inspection (from t9) of the second substrate wafer 100 and the second inspection (from t14) of the first substrate wafer 100, in the case of setting the time of the temporary crimping process to tb1, the time of the permanent crimping process to tb2, the inspection time to tt, and the standby time to tw, it may be set that tb1+tt<tt+tb2+tw; that is, tb1<tb2+tw.

As is clear from the above description, according to the example of FIG. 18, the step of serially performing the temporary crimping process and the permanent crimping process on one substrate wafer 100 can be efficiently executed. Further, if tb2<tb1<tb2+tw, one inspection apparatus 20 can inspect the substrate wafer 100 after the temporary crimping process and the permanent crimping process.

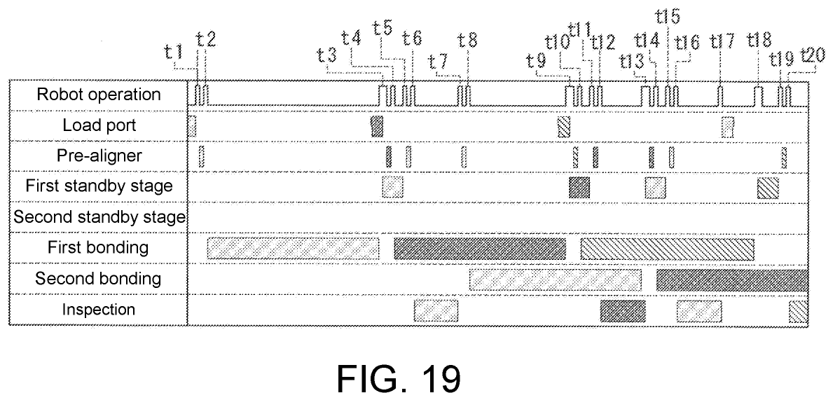

Next, another example of the operation timing will be described with reference to FIG. 19. The example of FIG. 19, as described with reference to FIGS. 13 and 14, is an example of the operation timing when bonding the first semiconductor chip 102f at the first bonding station 14f and bonding the second semiconductor chip 102s at the second bonding station 14s to one substrate wafer 100. In this case, since the first and second bonding stations 14f and 14s both heat the semiconductor chip 102 at a high temperature, every time the bonding process at the first and second bonding stations 14f and 14s is completed, it is necessary to cool the substrate wafer 100 on the standby stage 32.

More specifically, the first substrate wafer 100 (light ink) is transferred to the first bonding station 14f via the pre-aligner 30 (t1, t2). The first semiconductor chip 102f is bonded to the substrate wafer 100 at the first bonding station 14f. When this bonding process is completed, the transfer robot 28 transfers the first substrate wafer 100 to the standby stage 32 for the first substrate wafer 100 to cool (t3). In this state, since the first bonding station 14f has a vacancy, the transfer robot 28 transfers the second substrate wafer 100 (dark ink) to the first bonding station 14f (t3, t4). When the first substrate wafer 100 can be sufficiently cooled, the transfer robot 28 transfers the first substrate wafer 100 to the inspection apparatus 20 via the pre-aligner 30 (t5, t6).

When the inspection for the first substrate wafer 100 is completed, the transfer robot 28 transfers the first substrate wafer 100 to the second bonding station 14s via the pre-aligner 30 (t7, t8). The second semiconductor chip 102s is bonded to the first substrate wafer 100 at the second bonding station 14s. When this bonding process is completed, the first substrate wafer 100 is transferred to the inspection apparatus 20 via the standby stage 32 and the pre-aligner 30 (t13 to t16). Then, when the second inspection is completed, the first substrate wafer 100 is output to the load port 26 (t17). The second substrate wafer 100 is also processed in the same procedure as the first substrate wafer 100. Further, the third and subsequent substrate wafers 100 are also sequentially processed in the same manner.

As is clear from the above description, according to the example of FIG. 19, the step of serially bonding the first semiconductor chip 102f and the second semiconductor chip 102s to one substrate wafer 100 can be efficiently executed.

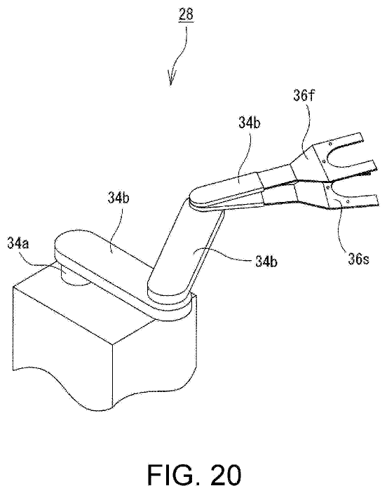

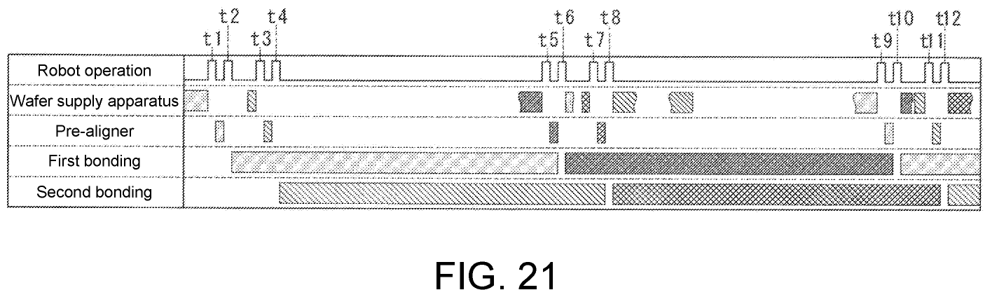

Next, another example will be described with reference to FIGS. 20 and 21. In the description above, one transfer robot 28 has only one holding hand 36 for attracting and holding the substrate wafer 100. In this case, in order to collect the substrate wafer 100 from one bonding station 14 and then supply a new substrate wafer 100, the transfer robot 28 needs to make two round trips between the load port 26 and the bonding station 14. Therefore, in order to reduce the number of round trips, as shown in FIG. 20, one transfer robot 28 may be provided with two holding hands 36. With such a configuration, the transfer robot 28 is capable of collecting the substrate wafer 100 from one bonding station 14 and then supplying a new substrate wafer 100 to this bonding station 14 on the spot without moving. As a result, the collection and supply of the substrate wafers 100 can be realized by one round-trip operation, and the processing time can be further shortened.

FIG. 21 is a diagram showing an example of the operation timing in this case. In the example of FIG. 21, the first bonding station 14f and the second bonding station 14s are driven independently of each other, and there is no movement of the substrate between the two bonding stations 14. However, as shown in FIG. 20, the transfer robot 28 having two holding hands 36 can also be used when one substrate wafer 100 is serially processed at the first and second bonding stations 14f and 14s.

In the example of FIG. 21, first, the first odd-numbered wafer W1O is transferred to the first bonding station 14f via the pre-aligner 30 (t1, t2). Further, during the execution period of the bonding process for the first odd-numbered wafer W1O, the second odd-numbered wafer W2O is transferred to the second bonding station 14s via the pre-aligner 30 (t3, t4).

When the bonding process at the first bonding station 14f is completed, the first odd-numbered wafer W1O and the first even-numbered wafer W1E are replaced. In order to perform this replacement, the first even-numbered wafer W1E is transferred to the pre-aligner 30 by the transfer robot 28 before the bonding process is completed, and its rotation angle is corrected (t5). After that, the transfer robot 28 moves to the first bonding station 14f with the first even-numbered wafer W1E attracted on the first holding hand 36f. Then, at the first bonding station 14f, the transfer robot 28 attracts and collects the first odd-numbered wafer W1O with the second holding hand 36s, and then places the first even-numbered wafer W1E on the first bonding station 14f (t6). Then, the transfer robot 28 moves to the load port 26 with the first odd-numbered wafer W1O attracted, and outputs the first odd-numbered wafer W1O to the load port 26. After that, the same process is repeated at the first and second bonding stations 14f and 14s, respectively.

As is clear from the above description, according to this example, since two holding hands 36 are provided in one transfer robot 28, the collection and supply of the substrate wafers 100 can be realized by one round-trip operation, and the processing time can be further shortened.

In addition, the configurations described above are examples, and they may be changed to other configurations as appropriate as long as at least one wafer transfer apparatus 12 may be shared by a plurality of bonding stations 14.

### DESCRIPTION OF REFERENCE NUMERALS

10: mounting apparatus; 12: wafer transfer apparatus; 14f: first bonding station; 14s: second bonding station; 16: bonding apparatus; 18: chip supply apparatus; 20: inspection apparatus; 22: bonding stage; 24: chip supply source; 26: load port; 28: transfer robot; 30: pre-aligner; 30a: rotary table; 30b: camera; 32: standby stage; 34: arm; 36: holding hand; 38: bonding head; 100: substrate wafer; 102: semiconductor chip; 104: metal bump

1. A mounting apparatus comprising:
a plurality of bonding stations, each of which has a bonding apparatus for bonding a semiconductor chip to a substrate wafer and a chip supply apparatus for supplying the semiconductor chip to the bonding apparatus; and
one wafer transfer apparatus for transferring the substrate wafer to supply the substrate wafer to each of the plurality of bonding stations and to collect the substrate wafer from each of the plurality of bonding stations.

2. The mounting apparatus according to claim 1,
wherein the bonding apparatus of each of the plurality of bonding stations is disposed adjacent to the wafer transfer apparatus, and
the chip supply apparatus of each of the plurality of bonding stations is disposed on an opposite side of the wafer transfer apparatus with the bonding apparatus interposed therebetween.

3. The mounting apparatus according to claim 1,
wherein the wafer transfer apparatus and the plurality of bonding stations cooperate with each other to form a chamber, and
the wafer transfer apparatus is capable of transferring the substrate wafer from one bonding station to another bonding station without exposing the substrate wafer to an outside of the chamber.

4. The mounting apparatus according to claim 1,
wherein the plurality of bonding stations comprise a first bonding station and a second bonding station disposed on an opposite side of the first bonding station with the wafer transfer apparatus interposed therebetween, and
the first bonding station, the wafer transfer apparatus, and the second bonding station are disposed side by side in a row.

5. The mounting apparatus according to claim 1, further comprising:
one inspection apparatus for inspecting the substrate wafer that has been processed,
wherein the one inspection apparatus is shared by the plurality of bonding stations.

6. The mounting apparatus according to claim 1,
wherein the wafer transfer apparatus comprises one transfer robot for transferring the substrate wafer and one pre-aligner for correcting a rotation angle of the substrate wafer, and
the one transfer robot and the one pre-aligner are shared by the plurality of bonding stations.

7. The mounting apparatus according to claim 1,
wherein the wafer transfer apparatus has a transfer robot capable of holding two substrate wafers simultaneously, and
the transfer robot is capable of collecting a substrate wafer that has been processed at one bonding station and then supplying a new substrate wafer on the spot without moving.

8. The mounting apparatus according to claim 1,
wherein the plurality of bonding stations comprise a first bonding station and a second bonding station, and
the wafer transfer apparatus supplies the substrate wafer that has been processed and collected from the first bonding station to the second bonding station.

9. The mounting apparatus according to claim 8,
wherein a temporary crimping process for temporarily crimping the semiconductor chip on the substrate wafer is executed at the first bonding station, and
a permanent crimping process for permanently crimping the temporarily crimped semiconductor chip is executed at the second bonding station.

10. The mounting apparatus according to claim 8,
wherein a process for bonding a first semiconductor chip to the substrate wafer is executed at the first bonding station, and
a process for bonding a second semiconductor chip different from the first semiconductor chip onto the first semiconductor chip is executed at the second bonding station.

11. The mounting apparatus according to claim 2,
wherein the wafer transfer apparatus and the plurality of bonding stations cooperate with each other to form a chamber, and
the wafer transfer apparatus is capable of transferring the substrate wafer from one bonding station to another bonding station without exposing the substrate wafer to an outside of the chamber.

12. The mounting apparatus according to claim 2,
wherein the plurality of bonding stations comprise a first bonding station and a second bonding station disposed on an opposite side of the first bonding station with the wafer transfer apparatus interposed therebetween, and
the first bonding station, the wafer transfer apparatus, and the second bonding station are disposed side by side in a row.

13. The mounting apparatus according to claim 3,
wherein the plurality of bonding stations comprise a first bonding station and a second bonding station disposed on an opposite side of the first bonding station with the wafer transfer apparatus interposed therebetween, and
the first bonding station, the wafer transfer apparatus, and the second bonding station are disposed side by side in a row.

14. The mounting apparatus according to claim 2, further comprising:
one inspection apparatus for inspecting the substrate wafer that has been processed,
wherein the one inspection apparatus is shared by the plurality of bonding stations.

15. The mounting apparatus according to claim 3, further comprising:
one inspection apparatus for inspecting the substrate wafer that has been processed,
wherein the one inspection apparatus is shared by the plurality of bonding stations.

16. The mounting apparatus according to claim 4, further comprising:
one inspection apparatus for inspecting the substrate wafer that has been processed,
wherein the one inspection apparatus is shared by the plurality of bonding stations.

17. The mounting apparatus according to-claim 2,
wherein the wafer transfer apparatus comprises one transfer robot for transferring the substrate wafer and one pre-aligner for correcting a rotation angle of the substrate wafer, and
the one transfer robot and the one pre-aligner are shared by the plurality of bonding stations.

18. The mounting apparatus according to-claim 3,
wherein the wafer transfer apparatus comprises one transfer robot for transferring the substrate wafer and one pre-aligner for correcting a rotation angle of the substrate wafer, and
the one transfer robot and the one pre-aligner are shared by the plurality of bonding stations.

19. The mounting apparatus according to claim 2,
wherein the wafer transfer apparatus has a transfer robot capable of holding two substrate wafers simultaneously, and
the transfer robot is capable of collecting a substrate wafer that has been processed at one bonding station and then supplying a new substrate wafer on the spot without moving.

20. The mounting apparatus according to claim 3,
wherein the wafer transfer apparatus has a transfer robot capable of holding two substrate wafers simultaneously, and
the transfer robot is capable of collecting a substrate wafer that has been processed at one bonding station and then supplying a new substrate wafer on the spot without moving.
